(19) United States
(12) Patent Application Publication
(10) Pub. No.: US 2014/0048862 A1
(43) Pub. Date: Feb. 20, 2014

(54) SEMICONDUCTOR DEVICE AND METHOD FOR FABRICATING SEMICONDUCTOR DEVICE

(71) Applicants: Junya Fujita, Mie (JP); Fumiki Aiso, Mie (JP); Ryu Kato, Mie (JP)

(72) Inventors: Junya Fujita, Mie (JP); Fumiki Aiso, Mie (JP); Ryu Kato, Mie (JP)

(21) Appl. No.: 13/715,324

(22) Filed: Dec. 14, 2012

Related U.S. Application Data
(60) Provisional application No. 61/683,762, filed on Aug. 16, 2012.

(51) Int. Cl. H01L 29/788; H01L 21/762

(52) U.S. Cl. CPC H01L 29/788; H01L 21/762
USPC 257/314; 438/424

(57) ABSTRACT

A semiconductor device according to an embodiment, includes a first dielectric film, a floating gate, a second dielectric film, and a third dielectric film. The first dielectric film is formed above a semiconductor substrate. The floating gate is formed above the first dielectric film by using a silicon film. The third dielectric film is formed to cover an upper surface of the floating gate and a side face portion of the floating gate. The floating gate includes an impurity layer formed on an upper surface of the floating gate and a side face of the floating gate along an interface between the floating gate and the third dielectric film formed to cover the upper surface of the floating gate and a side face portion of the floating gate and containing at least one of carbon (C), nitrogen (N), and fluorine (F) as an impurity.

### CROSS-REFERENCE TO RELATED APPLICATION

This application is based upon and claims the benefit of priority from U.S. Patent Application No. 61/683,762 filed on Aug. 16, 2012 in U.S.A., the entire contents of which are incorporated herein by reference.

### FIELD

Embodiments described herein relate generally to a semiconductor device and a method for fabricating a semiconductor device.

### BACKGROUND

In development of a semiconductor device, particularly a semiconductor storage apparatus, memory cells are made increasingly finer to achieve a larger capacity, lower cost and the like. In a semiconductor storage apparatus mounted with a floating gate structure of a NAND nonvolatile semiconductor memory device, for example, a wiring pitch between word lines to be a control gate in a gate portion is made ever finer. Such a finer structure of LSI is actively promoted for the purpose of achieving performance improvement such as faster operations of device and lower power consumption due to higher integration and curbing fabricating costs. In recent years, flash memories whose minimum processing dimension is about, for example, 20 nm are fabricated at a mass production level and still finer structures are expected to be developed, increasing technical difficulty.

An electrically data rewritable NAND nonvolatile semiconductor memory device changes the amount of charge of a floating gate in a cell transistor and thus, data is stored by changing the threshold voltage thereof. Generally, electrons are emitted and injected between a floating gate and a semiconductor substrate via a gate dielectric film. The amount of charge of the floating gate is thereby controlled. However, various problems arise as circuit structures become still finer in response to requests of finer structures in recent years.

Because the physical thickness of an IPD (Inter Poly Dielectric) film cannot be made thinner, a space between adjacent floating gates in a device isolation direction is filled with an IPD film, posing a problem of difficulty of embedding a control gate between adjacent floating gates as a limit to making a memory cell finer. Alternatively, a problem is posed that even if a control gate is embedded, the control gate embedded is too thin to function as an electrode. To solve such a problem, for example, an attempt is made to change the polarity of the floating gate from the n type to the p type. An n-type floating gate does not have sufficient charge holding capacity because electrons build up in a tunnel dielectric film or IPD film interface of the floating gate after writing. In a p-type floating gate, by contrast, electrons recombine with holes after writing and no electron is present in the conduction band and thus, the p-type floating gate is considered to excel in charge holding properties. Therefore, the thickness of a tunnel dielectric film can be made thinner and when the same coupling ratio is maintained, it becomes possible to make an IPD dielectric film thinner and reduce the height of the floating gate. The tunnel dielectric film is thin and carriers are injected into a p-type floating gate during write operation and thus, it becomes possible to write at a low voltage. Accordingly, the leak current of the IPD dielectric film can also be reduced. Therefore, the aspect ratio can be lowered by making an IPD film thinner or reducing the height of a floating gate through the adoption of a p-type floating gate so that still finer cells can be formed.

However, if a p-type floating gate is adopted, a problem of depletion due to insufficient active carriers is posed. This can be considered to be caused by the shortage of electrically active boron (B) after boron goes out during cell processing or boron is inactivated by a heating process even if a sufficient amount of boron as a p-type dopant is doped.

### BRIEF DESCRIPTION OF THE DRAWINGS

FIG. 1 is a flowchart showing principal part processes of a method for fabricating a semiconductor device according to a first embodiment;

FIGS. 2A and 2B are process sectional views of the method for fabricating a semiconductor device according to the first embodiment;

FIGS. 3A and 3B are process sectional views of the method for fabricating a semiconductor device according to the first embodiment;

FIGS. 4A and 4B are process sectional views of the method for fabricating a semiconductor device according to the first embodiment;

FIGS. 5A and 5B are process sectional views of the method for fabricating a semiconductor device according to the first embodiment;

FIGS. 6A and 6B are process sectional views of the method for fabricating a semiconductor device according to the first embodiment;

FIGS. 7A and 7B are process sectional views of the method for fabricating a semiconductor device according to the first embodiment;

FIGS. 8A and 8B are process sectional views of the method for fabricating a semiconductor device according to the first embodiment;

FIGS. 9A and 9B are process sectional views of the method for fabricating a semiconductor device according to the first embodiment;

FIGS. 10A and 10B are process sectional views of the method for fabricating a semiconductor device according to the first embodiment;

FIGS. 11A and 11B are process sectional views of the method for fabricating a semiconductor device according to the first embodiment;

FIGS. 12A and 12B are process sectional views of the method for fabricating a semiconductor device according to the first embodiment; and

FIGS. 13A and 13B are sectional views showing a state in which an inter-level dielectric is formed after a gate structure is formed by the method for fabricating a semiconductor device according to the first embodiment.

### DETAILED DESCRIPTION

A semiconductor device according to an embodiment, includes a first dielectric film, a floating gate, a second dielectric film, and a third dielectric film. The first dielectric film is formed above a semiconductor substrate. The floating gate is formed above the first dielectric film by using a silicon film. The second dielectric film for element isolation of semiconductor elements is arranged on a side of a side face of the floating gate and embedded between a height position of a lower portion of the side face of the floating gate and a height position inside the semiconductor substrate. The third dielectric film is formed to cover an upper surface of the floating gate and a side face portion of the floating gate up to a height position of an upper surface of the second dielectric film, of the side face of the floating gate continuing from the upper surface of the floating gate. The floating gate includes an impurity layer formed on the upper surface of the floating gate and the side face of the floating gate along an interface between the floating gate and the third dielectric film and containing at least one of carbon (C), nitrogen (N), and fluorine (F) as an impurity.

A method for fabricating a semiconductor device according to an embodiment, includes forming a first dielectric film above a semiconductor substrate; forming a floating gate material film above the first dielectric film by using silicon; forming openings for element isolation passing through the floating gate material film and the first dielectric film and halfway through the semiconductor substrate; filling the openings with a second dielectric film; etching the second dielectric film up to a height position halfway through the floating gate material film; doping at least one of carbon (C), nitrogen (N), and fluorine (F) into an upper surface and a side face of the floating gate material film as an impurity after the etching; and forming a third dielectric film along an impurity layer formed on the upper surface of the floating gate material film and a side face portion of the floating gate material film up to a height position of an upper surface of the second dielectric film, of the side face of the floating gate material film by the impurity being doped.

### First Embodiment

The first embodiment will be described about a configuration in which an impurity layer using at least one of carbon (C), nitrogen (N), and fluorine (F) as an impurity is formed on the upper surface and side face of a floating gate (charge storage layer) using a p-type semiconductor film. In the first embodiment, a method for fabricating a nonvolatile NAND flash memory device as an example of the semiconductor device will be described. However, the method for fabricating a semiconductor device described below is not limited to the NAND flash memory device and is also effective for other floating gate semiconductor devices. The first embodiment will be described below using the drawings.

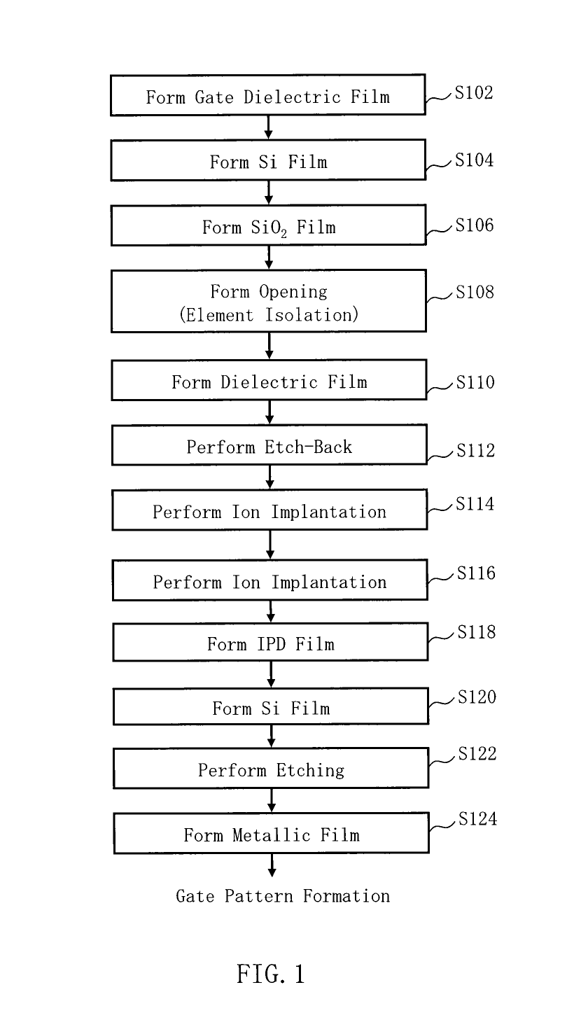

FIG. 1 is a flowchart showing principal part processes of a method for fabricating a semiconductor device according to a first embodiment. In FIG. 1, the method for fabricating a semiconductor device according to the first embodiment executes a series of processes including a gate dielectric film formation process (S102), a silicon (Si) film formation process (S104), a silicon oxide (SiO₂) film formation process (S106), an opening formation process (S108), a dielectric film formation process (S110), an etch-back process (S112), an ion implantation process (S114), an ion implantation process (S116), an interpoly dielectric film (IPD film) formation process (S118), an Si film formation process (S120), an etching process (S122), and a metallic film formation process (S124).

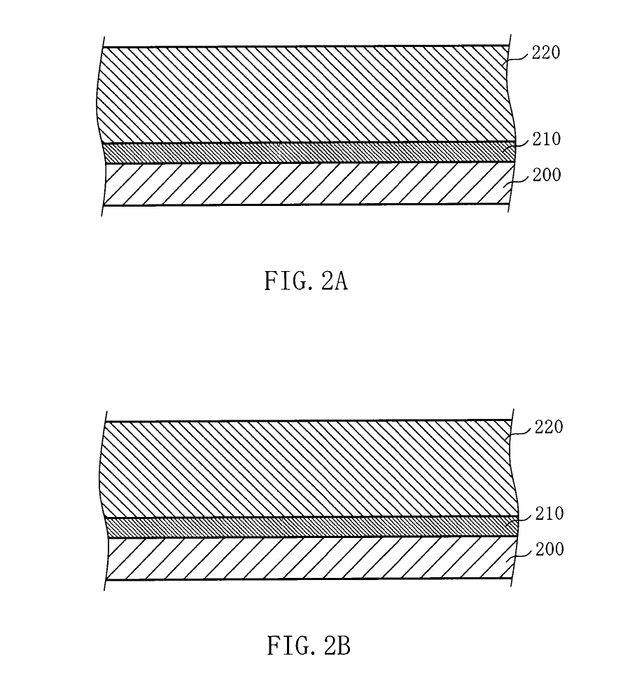

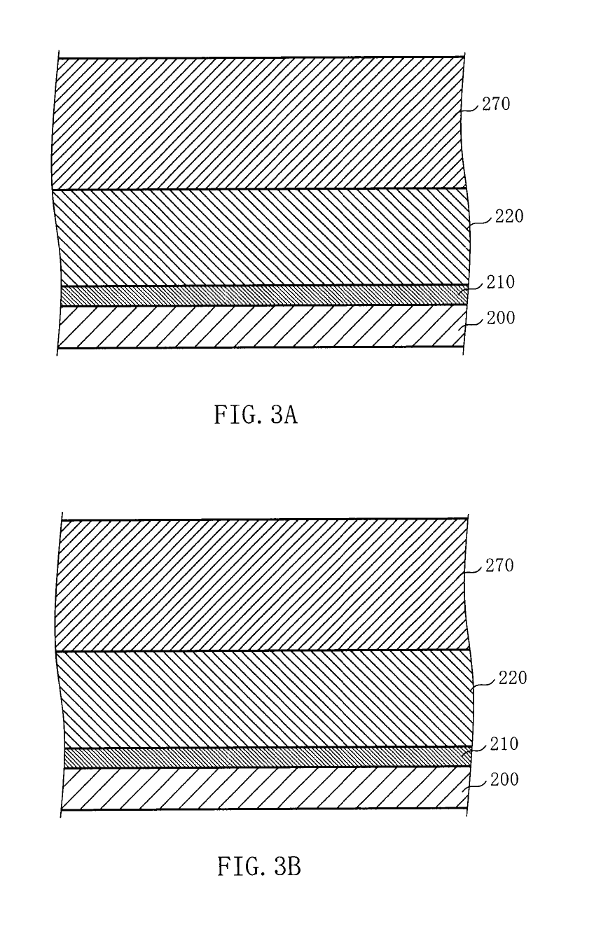

FIGS. 2A and 2B show process sectional views of the method for fabricating a semiconductor device according to the first embodiment. FIGS. 2A and 2B show the gate dielectric film formation process (S102) and the silicon (Si) film formation process (S104) in FIG. 1. Subsequent processes will be described later. FIG. 2A shows a section of a cell region (first region) in which a gate structure to be a memory cell will be formed. FIG. 2B shows a section of a peripheral circuit region (second region) in which a peripheral circuit arranged in the periphery of the memory cell will be formed. FIGS. 2A and 2B show sections in a direction along the longitudinal direction of a control gate (CG) (word line). In diagrams subsequent to FIGS. 2A and 2B, it is assumed that FIGS. 3A to 13A each show sections in a direction along the longitudinal direction of the control gate (CG) (word line) of the cell region and FIGS. 3B to 13B each show sections in a direction along the longitudinal direction of the control gate (CG) (word line) of the peripheral circuit region.

In FIGS. 2A and 2B, as the gate dielectric film formation process (S102), a dielectric film 210 (first dielectric film) is formed on a semiconductor substrate 200 to a thickness of, for example, 1 to 15 nm. The dielectric film 210 functions as a tunnel dielectric film (gate dielectric film). For example, a silicon oxide (SiO₂) film or silicon oxynitride film is used as the dielectric film 210. The SiO₂ film is suitably formed by, for example, heat treatment (thermal oxidation treatment) in an oxygen atmosphere. The silicon oxynitride film is suitably formed by, for example, combining heat treatment (thermal oxidation treatment) in an oxygen (O₂) atmosphere and heat treatment (thermal nitridization treatment) in a nitrogen (N₂) atmosphere. For example, a p-type silicon substrate made of a silicon wafer of 300 mm in diameter is used as the semiconductor substrate 200.

Next, as the Si film formation process (S104), an Si film 220 (floating gate (FG) material film) is formed on the dielectric film 210 to a thickness of, for example, 100 nm. The Si film 220 is formed by the low-pressure chemical vapor deposition (LP-CVD) method by which, for example, a mono-silane (SiH₄) gas and boron trichloride (BCl₃) gas are supplied as raw materials of an amorphous silicon film and the film formation temperature is controlled to 350 to 550° C. When an amorphous silicon film is formed, a p-type amorphous silicon film can be formed by introducing boron (B) to be a p-type dopant into a chamber. The p-type amorphous silicon film is converted into a p-type polysilicon film by a subsequent heating process (for example, the next SiO₂ film formation process (S106)). When the amorphous silicon film is formed, boron (B) to be a p-type dopant is introduced into a chamber, but the formation method is not limited to the above example. After a non-doped amorphous silicon film being formed, boron (B) maybe doped or “injected” into the amorphous silicon film by an ion implantation method (not shown).

FIGS. 3A and 3B show process sectional views of the method for fabricating a semiconductor device according to the first embodiment. FIGS. 3A and 3B show the SiO₂ film formation process (S106) in FIG. 1. Subsequent processes will be described later.

In FIGS. 3A and 3B, as the SiO₂ film formation process (S106), an SiO₂ film 270 is formed by using the chemical vapor deposition (CVD) method to a thickness of, for example, 50 to 400 nm. The SiO₂ film 270 becomes a protective film of the Si film 220 in the opening formation process (S108) described later.

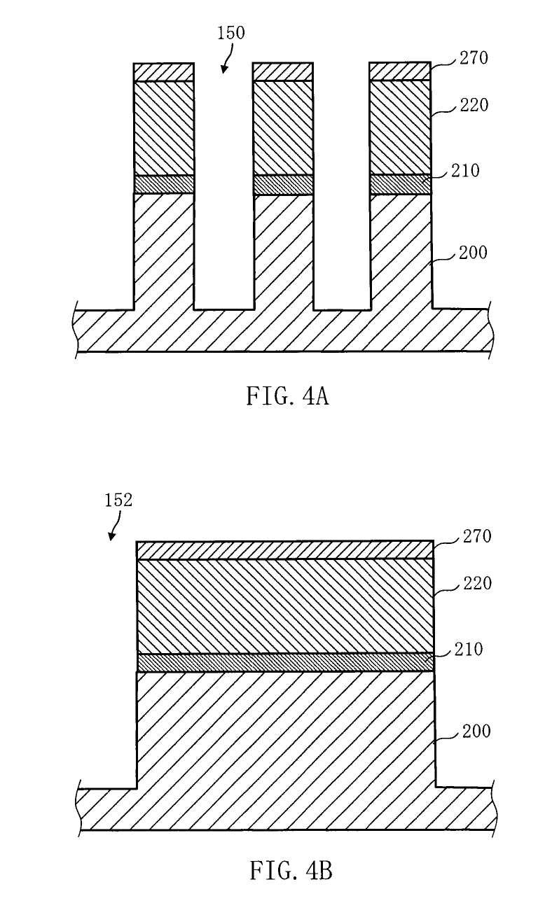

FIGS. 4A and 4B show process sectional views of the method for fabricating a semiconductor device according to the first embodiment. FIGS. 4A and 4B show the opening formation process (S108) in FIG. 1. Subsequent processes will be described later.

In FIGS. 4A and 4B, as the opening formation process (S108), an opening 150 in a groove shape passing through the SiO₂ film 270, the Si film 220, and the dielectric film 210 and halfway through the semiconductor substrate 200 is formed. In a memory cell region shown in FIG. 4A, for example, the opening 150 of the width 20 nm or less is formed at intervals of 40 nm or less. In a peripheral circuit region shown in FIG. 4B, for example, an opening 152 of the width 100 nm or less is formed at intervals of 200 nm or less. The opening can be formed substantially perpendicularly to the surface of the semiconductor substrate 200 by removing the exposed SiO₂ film 270 and the p-type Si film 220, the dielectric film 210, and the semiconductor substrate 200 positioned as lower layers of the SiO₂ film 270 by the anisotropic etching method from the semiconductor substrate 200 having a resist film formed on the SiO₂ film 270 by undergoing a lithography process such as a resist coating process and exposure process (not shown). For example, the opening may be formed, as an example, by the reactive ion etching (RIE) method. The openings 150, 152 become element isolation regions.

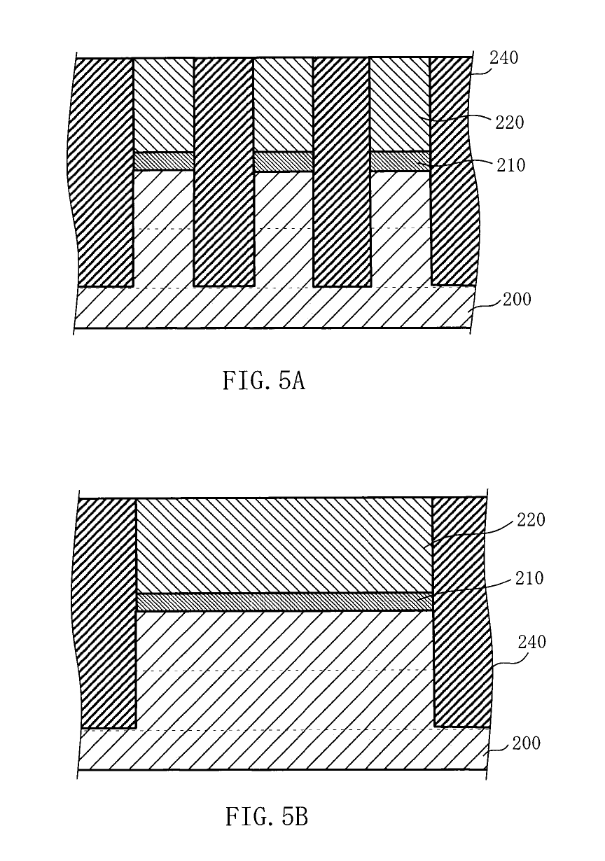

FIGS. 5A and 5B show process sectional views of the method for fabricating a semiconductor device according to the first embodiment. FIGS. 5A and 5B show the dielectric film formation process (S110) in FIG. 1. Subsequent processes will be described later.

In FIGS. 5A and 5B, as the dielectric film formation process (S110), a dielectric film 240 (second dielectric film) is formed in the openings 150, 152 like burying the openings 150, 152 and on the SiO₂ film 270 by using, for example, the CVD method, the coating process or the like.

Then, as a planarization process, the dielectric film 240 bulging out of the openings 150, 152, the dielectric film 240 on the SiO₂ film 270, and the SiO₂ film 270 are polished and removed by the CMP method for planarization. Accordingly, as shown in FIG. 5A, element isolation between memory cells is realized. Similarly, as shown in FIG. 53, the dielectric film 240 is also arranged on the side face side of a peripheral circuit and can realize element isolation of devices of the peripheral circuit. For example, an SiO₂ film is used as the dielectric film 240.

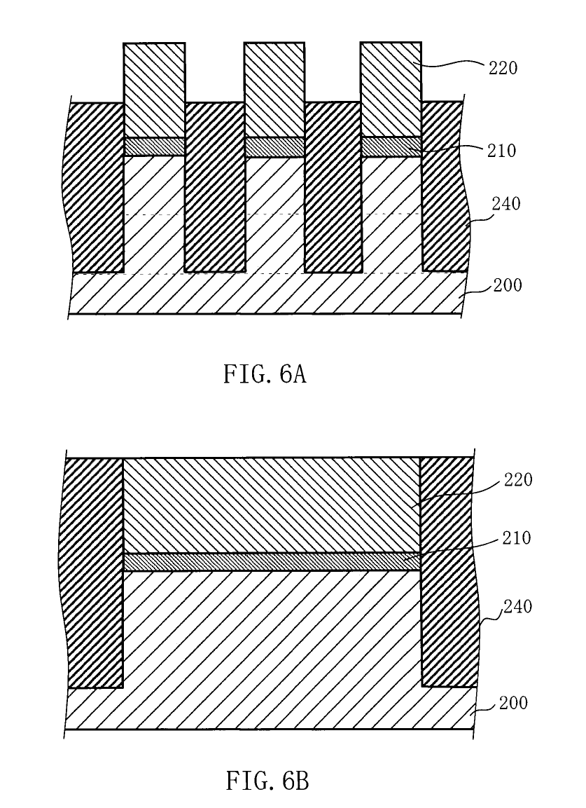

FIGS. 6A and 6B show process sectional views of the method for fabricating a semiconductor device according to the first embodiment. FIGS. 6A and 6B show the etch-back process (S112) in FIG. 1. Subsequent processes will be described later.

In FIG. 6A, as the etch-back process (S112), the dielectric film 240 is etched by the etch-back method. Here, the surface of the dielectric film 240 for element isolation in the memory cell region is dug by performing etching up to the height position at a midpoint of the p-type Si film 220 in the memory cell region shown in FIG. 6A using photolithography technology, RIE technology, or wet etching technology. Accordingly, an upper side face of the Si film 220 to be an FG polysilicon film is exposed. On the other hand, as shown in FIG. 6B, the resist film (not shown) is suitably left to leave the dielectric film 240 for element isolation without etching outside the memory cell region. Accordingly, the exposed surface area per volume of the Si film 220 in the peripheral circuit region can be made smaller than the exposed surface area per volume of the Si film 220 in the memory cell region.

The dielectric film 240 is, as described above, arranged on the side face side of the FG and embedded between the height position of a side face lower portion of the FG and the height position inside the semiconductor substrate 200 for element isolation (shallow trench isolation structure: STI) of memory cells (semiconductor elements) in a gate structure.

Boron (B) in the Si film 220 is deposited in a defective portion or interface by heat treatment in a process subsequent to the formation of the Si film 220 and further, boron (B) in the Si film 220 goes out in the etch-back process (S112). In addition, boron (B) in the Si film 220 is inactivated by heat treatment in other processes. Accordingly, a shortage of electrically active boron (B) in the Si film 220 is caused. Therefore, the depletion layer in the FG increases if nothing is done. Therefore, according to the first embodiment, as will be described below, impurities are intentionally introduced from the exposed surface of the Si film 220.

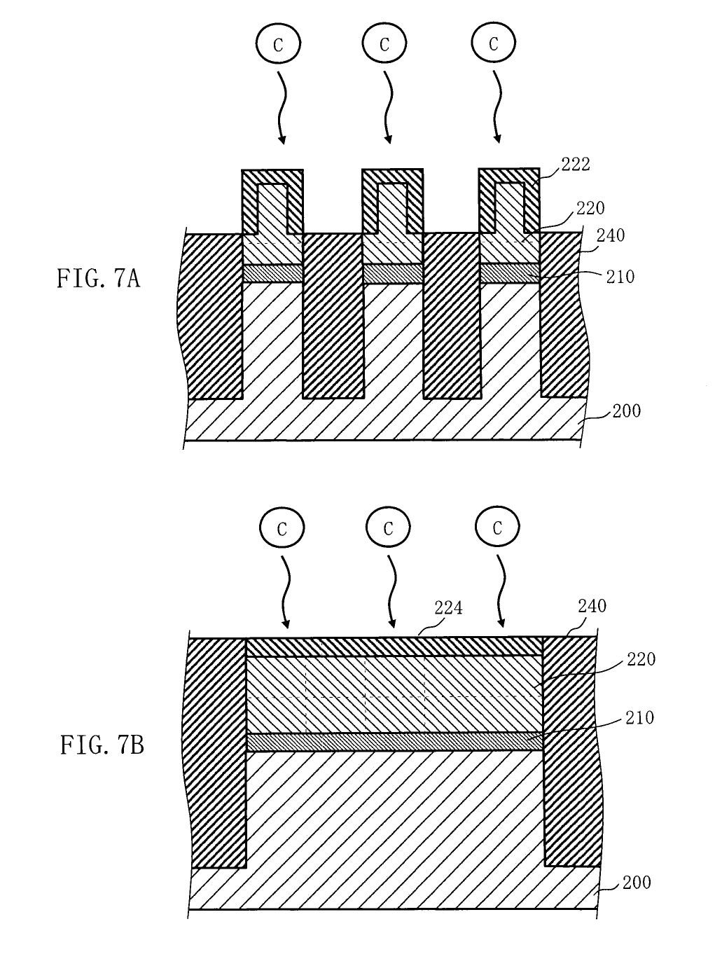

FIGS. 7A and 7B show process sectional views of the method for fabricating a semiconductor device according to the first embodiment. FIGS. 7A and 7B show the ion implantation process (S114) in FIG. 1. Subsequent processes will be described later.

In FIG. 7A, as the ion implantation process (S114), an impurity layer 222 is formed on the upper surface and side face of the Si film 220 in the memory cell region by doping or “injecting” at least one of carbon (C), nitrogen (N), and fluorine (F) as an impurity. At the same time, as shown in FIG. 7B, an impurity layer 224 is formed on the upper surface of the Si film 220 in the peripheral circuit region by doping at least one of carbon (C), nitrogen (N), and fluorine (F) as an impurity. Thus, the impurity layers 222, 224 are semiconductors formed near the interface of the p-type Si film 220. The impurity layers 222, 224 are suitably formed to a thickness of more than 1 nm and 10 nm or less. Here, for example, C is doped as an impurity. The concentration of impurities in the impurity layers 222, 224 is suitably controlled to 1×10¹⁸ to 1×10²²/cm³. By controlling the concentration to the above range, the Si film 220 can be prevented from becoming a dielectric film. By forming the impurity layer 222 on the exposed surface of the Si film 220 in the memory cell region, defects that are hard to recover are intentionally introduced by heat into the Si film 220 so that depletion can be curbed by generating carriers when an electric field is applied after the product is completed. The defects in the impurity layer 222 also have an effect of curbing out diffusion of boron and as a result, an effect of increased boron remaining in the FG in the end can also be expected. When a p-type FG is used, the upper portion of the FG is depleted during writing and thus, it is preferable to introduce defects in the upper portion of the FG. Therefore, according to the first embodiment, by doping an impurity into the exposed surface of the p-type Si film 220, the concentration of the impurity in a portion of the FG above the height position of the upper surface of the dielectric film 240 on the side face of the FG can be made higher than in a portion of the FG below the height position of the upper surface of the dielectric film 240. If the impurity layer 222 is formed to a thickness of 10 nm when the width dimension of the FG is 20 nm or less, the entire upper portion of the FG above the height position of the upper surface of the dielectric film 240 on the side face becomes the impurity layer 222 and it makes no difference if such a state arises.

According to the first embodiment, as shown in FIG. 7A, the impurity layer 222 is formed by doping an impurity into the exposed upper surface and exposed side face of the Si film 220 in the memory cell region so as to cover the upper surface and the side face portion of the FG up to the height position of the surface of the dielectric film 240 of the side face continuing from the upper surface. On the other hand, as shown in FIG. 7B, the impurity layer 224 is formed by doping an impurity into the upper surface only of the Si film 220 in the peripheral circuit region and no impurity layer is formed on the side face. Thus, the concentration per volume of impurity in the Si film 220 in the memory cell region to be a floating gate can be made higher than in the Si film 220 in the peripheral circuit region to be a peripheral circuit. When the Si film 220 is used as a resistance element, gate of a transistor or the like in the peripheral circuit, if an impurity of the concentration per volume comparable to that in the Si film 220 in the memory cell region, the resistance increases too much and the circuit may not operate as designed. However, like in the first embodiment, the impurity concentration in the Si film 220 in the peripheral circuit region can be held down when compared with the Si film 220 in the memory cell region. Therefore, even if the Si film 220 in the peripheral circuit region is used as, for example, a resistance element, the resistance of the resistance element can be prevented from increasing. Even if the dielectric film 240 in the peripheral circuit region is etched back in the etch-back process (S112) shown in FIGS. 6A and 6B, the area of the upper surface of the Si film 220 in the memory cell region formed with the minimum pitch is generally small and the ratio of the side face exposed by etch-back to the entire area of the exposed surface of the Si film 220 becomes very large when compared with the peripheral circuit. Accordingly, the exposed surface area per volume of the Si film 220 can be made larger on the memory cell region side than the peripheral circuit region side and thus, the impurity concentration per volume can be held down on the peripheral circuit region side.

Such an impurity can suitably be doped by using the plasma doping (PD) method by which a dopant is doped by exposing a substrate to a plasma atmosphere containing the dopant. Because an impurity is not introduced by thermal diffusion in the plasma doping method, it is difficult to take the selection ratio of the dielectric film 240 for element isolation and the Si film 220, but the dopant can easily be introduced even if the concentration is relatively high. Because an impurity can be introduced at low temperature, the impurity can selectively be doped into the memory cell region while leaving a resist film or the like outside the memory cell region after the etch-back process (S112). When C is doped as an impurity in the plasma doping method, the impurity layer 222 can be formed on the exposed top surface and exposed upper side face of the Si film 220 by exposing the Si film 220 at ordinary temperature in a plasma atmosphere using, for example, a CH₄ gas and a CF₄ gas as source gases. In this case, a carrier gas can be made unnecessary. In addition to the CH₄ gas, a C₂H₄ gas or the like may be used as a source gas. When N is doped, for example, an ammonium (NH₃) gas may be used as a source gas. In addition to the NH₃ gas, a nitrogen (N₂) gas or N₂O gas may be used as a source gas. In this case, hydrogen (H₂) or helium (He) may be supplied as a carrier gas. When F is doped, for example, a fluorine (F₂) gas may be used as a source gas. In this case, H₂ or He may be supplied as a carrier gas.

Alternatively, an impurity may be doped by using the gas phase doping (GPD) method by which a dopant is doped by heat treatment of a substrate in a gas atmosphere containing the dopant. An impurity is introduced by thermal diffusion in the gas phase doping method and thus, a dopant can selectively be doped into the Si film 220 under conditions that take the selection ratio of the dielectric film 240 for element isolation and the Si film 220 into consideration. When C is doped as an impurity in the gas phase doping method, the impurity layer 222 can be formed on the exposed top surface and exposed upper side face of the Si film 220 by heat treatment of the Si film 220 at 700 to 900° C. in a gas atmosphere using, for example, a CH₄ gas and a CF₄ gas as source gases. In this case, a carrier gas can be made unnecessary. In addition to the CH₄ gas, a C₂H₄ gas or the like may be used as a source gas. When N is doped, for example, an NH₃ gas may be used as a source gas. In addition to the NH₃ gas, an N₂ gas or N₂O gas maybe used as a source gas. In this case, H₂ or He may be supplied as a carrier gas. When F is doped, for example, an F₂ gas may be used as a source gas. In this case, H₂ or He may be supplied as a carrier gas.

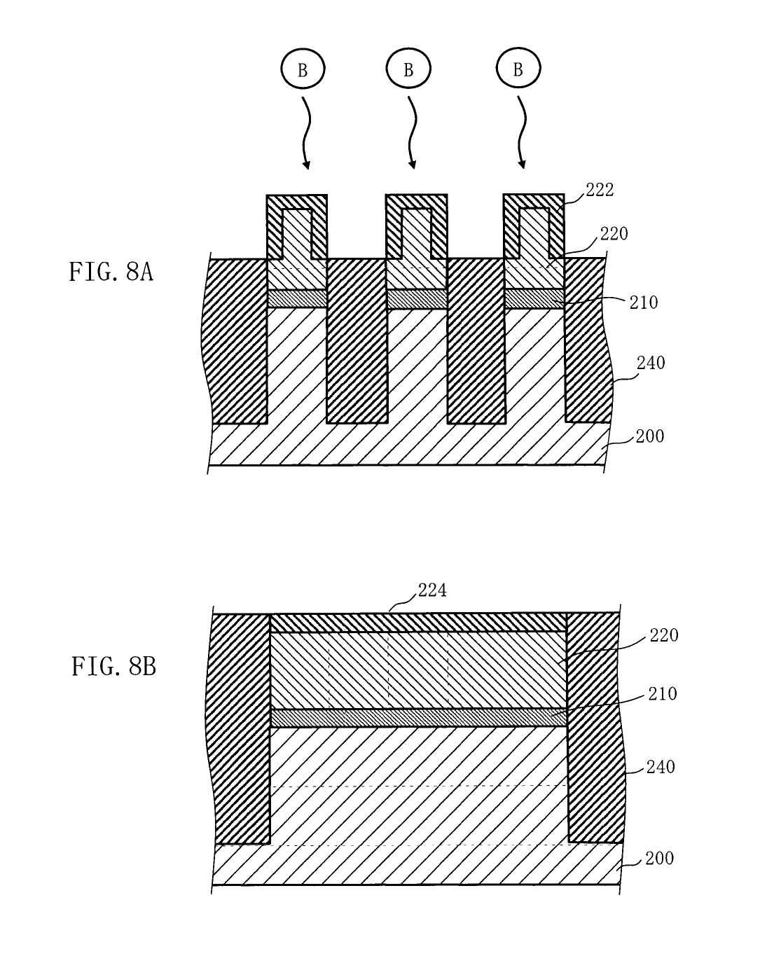

FIGS. 8A and 8B show process sectional views of the method for fabricating a semiconductor device according to the first embodiment. FIGS. 8A and 8B show the ion implantation process (S116) in FIG. 1. Subsequent processes will be described later.

In FIG. 8A, as the ion implantation process (S116), boron (B) is doped into the upper surface and side face of the Si film 220 on the memory cell region as a p-type dopant. Accordingly, B as an insufficient p-type dopant can be replenished and further, depletion when an electric field is applied after the product is completed can be curbed. Incidentally, it is suitable not to further inject boron (B) into the Si film 220 in the peripheral circuit region shown in FIG. 8B. Because the p type is converted into the n type in the peripheral circuit in the end, it is better not to consciously inject B here. Alternatively, next, a conversion into the n-type Si film 220 may be made by doping an n-type impurity into the Si film 220 in the peripheral circuit region shown in FIG. 8B.

The ion implantation process (S116) in which B is doped as a p-type dopant is performed after the ion implantation process (S114) in which at least one of C, N, and F is doped as an impurity, but the ion implantation is not limited to the above example. When at least one of C, N, and F is doped as an impurity, B may be doped into the Si film 220 together. Alternatively, B may be doped into the Si film 220 after the etch-back process (S112) and before at least one of C, N, and F is doped as an impurity and in this case, B can selectively be doped into the memory cell region while leaving a resist film or the like outside the memory cell region. Alternatively, the ion implantation process (S116) itself may be omitted. Depletion can be curbed by the ion implantation process (S114) alone without doping B again.

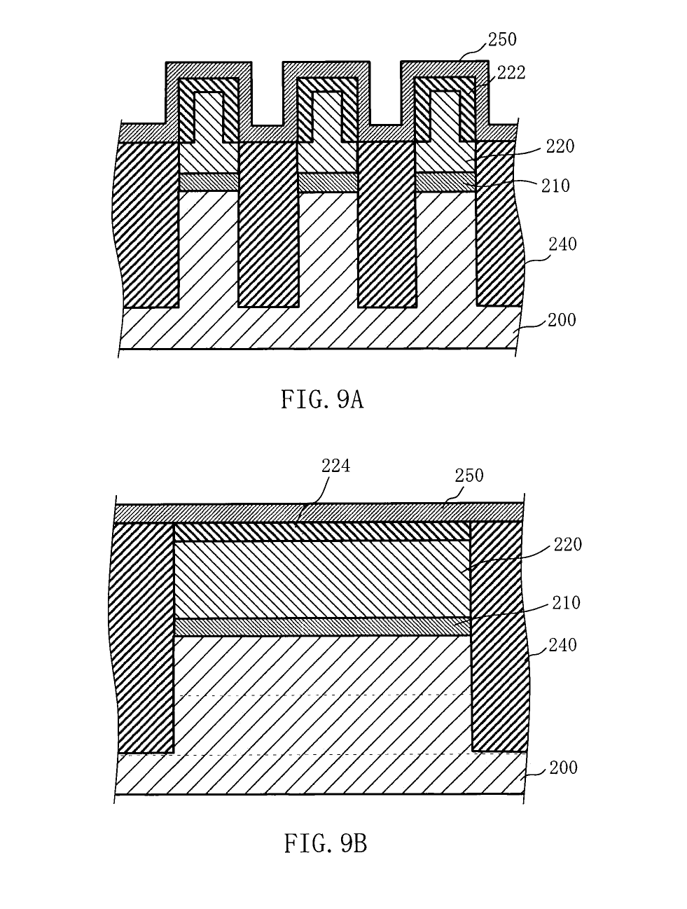

FIGS. 9A and 9B show process sectional views of the method for fabricating a semiconductor device according to the first embodiment. FIGS. 9A and 9B show the IPD film formation process (S118) in FIG. 1. Subsequent processes will be described later.

In FIG. 9A, as the IPD film formation process (S118), after an impurity such as C, N, or F being doped, an interpoly dielectric film (IPD) 250 (third dielectric film) is formed, for example, by using the CVD method to cover the upper surface of the Si film 220 to be an FG and a side face portion of the Si film 220 up to the height position of the surface of the dielectric film 240 of the side face of the Si film 220 continuing from the upper surface and also on the dielectric film 240 to a thickness of, for example, 5 to 20 nm. The IPD film 250 functions as an inter-electrode dielectric film in a gate structure of the memory cell region. In the peripheral circuit region, as shown in FIG. 9B, the IPD film 250 is formed on the upper surface of the Si film 220 and on the dielectric film 240. The IPD film 250 suitably uses a high-dielectric dielectric film, laminated structure of a silicon oxide film/high-dielectric film/silicon oxide film, laminated structure of a silicon oxide film/silicon nitride film/silicon oxide film, or laminated structure in which the above laminated structured are sandwiched between nitride films.

From the above, the impurity layer 222 containing at least one of C, N, and F as an impurity is formed on the upper surface and side face of the Si film 220 to be a floating gate along the interface between the floating gate and the IPD film 250. The impurity layer 222 is formed in the entire interface between the floating gate and the IPD film 250.

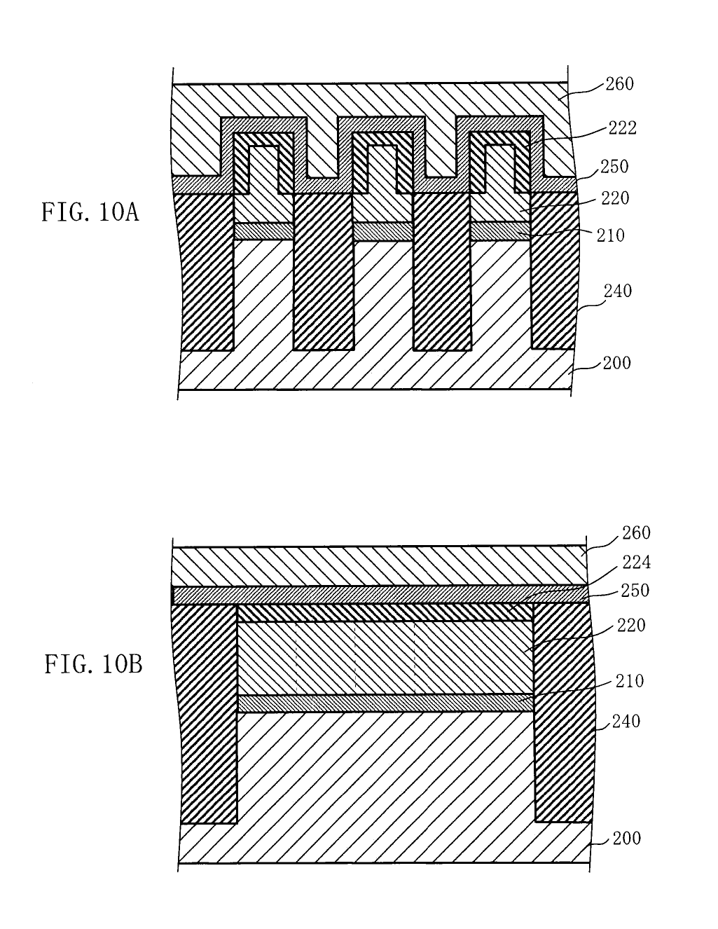

FIGS. 10A and 10B show process sectional views of the method for fabricating a semiconductor device according to the first embodiment. FIGS. 10A and 10B show the Si film formation process (S120) in FIG. 1. Subsequent processes will be described later.

In FIG. 10A, as the Si film formation process (S120), an Si film 260 is formed on the IPD film 250 by using, for example, the CVD method to a thickness of, for example, 10 to 60 nm. The Si film 260 is formed by the LP-CVD method by which, for example, an SiH₄ gas and BCl₃ gas are supplied as raw materials of an amorphous silicon film and the film formation temperature is controlled to 350 to 550° C. The amorphous silicon film is converted into a polysilicon film by a subsequent heating process. The Si film 260 to be a polysilicon film functions as a portion of the control gate (CG) . In this manner, the control gate is formed on the IPD film 250. In the first embodiment, a p-type FG is formed and thus, the aspect ratio can be lowered by making the IPD film 250 thinner or reducing the height of the FG and the IPD film 250 can be prevented from embedding a space between FGs adjacent in the element isolation direction. Therefore, the Si film 260 to be a portion of the CG can be embedded in the space between FGs and caused to function as an electrode. In the peripheral circuit region, as shown in FIG. 10B, the Si film 260 is formed on the IPD film 250.

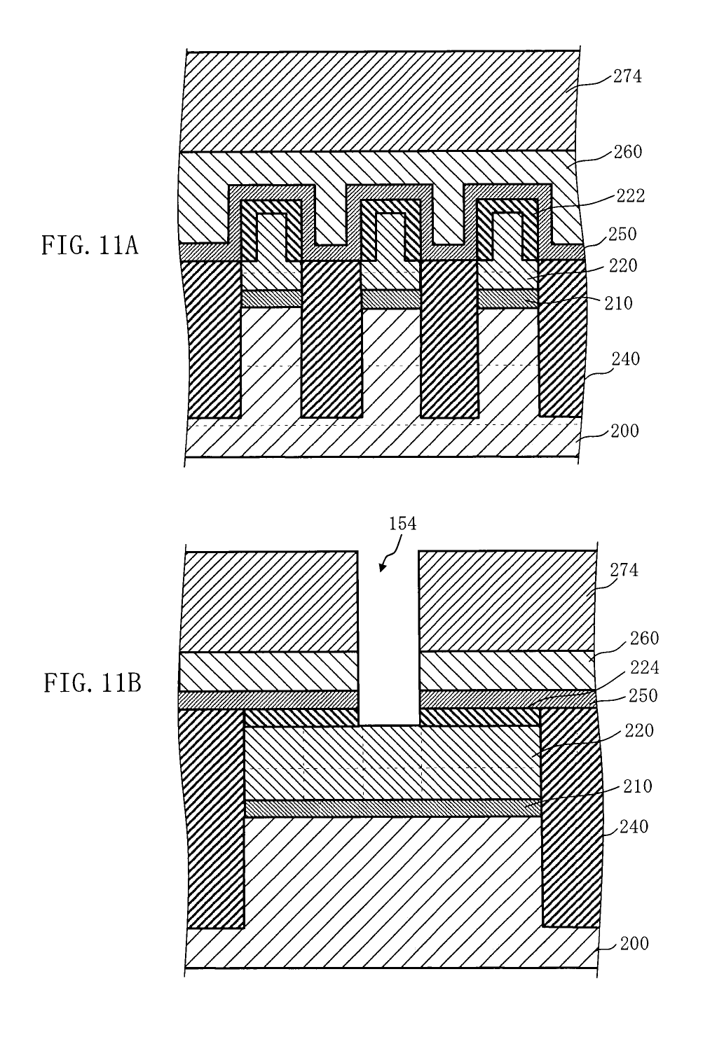

FIGS. 11A and 11B show process sectional views of the method for fabricating a semiconductor device according to the first embodiment. FIGS. 11A and 11B show the etching process (S122) in FIG. 1. Subsequent processes will be described later.

In FIG. 11B, as the etching process (S122), after a resist film 274 being formed on the Si film 260, an opening 154 is formed in a portion of the Si film 260 and a portion of the IPD dielectric film 250 in the peripheral circuit region by using photolithography technology and RIE technology. After the opening 154 being formed, the remaining resist film 274 may be removed by ashing or the like. On the other hand, as shown in FIG. 11A, no opening is formed in the memory cell region.

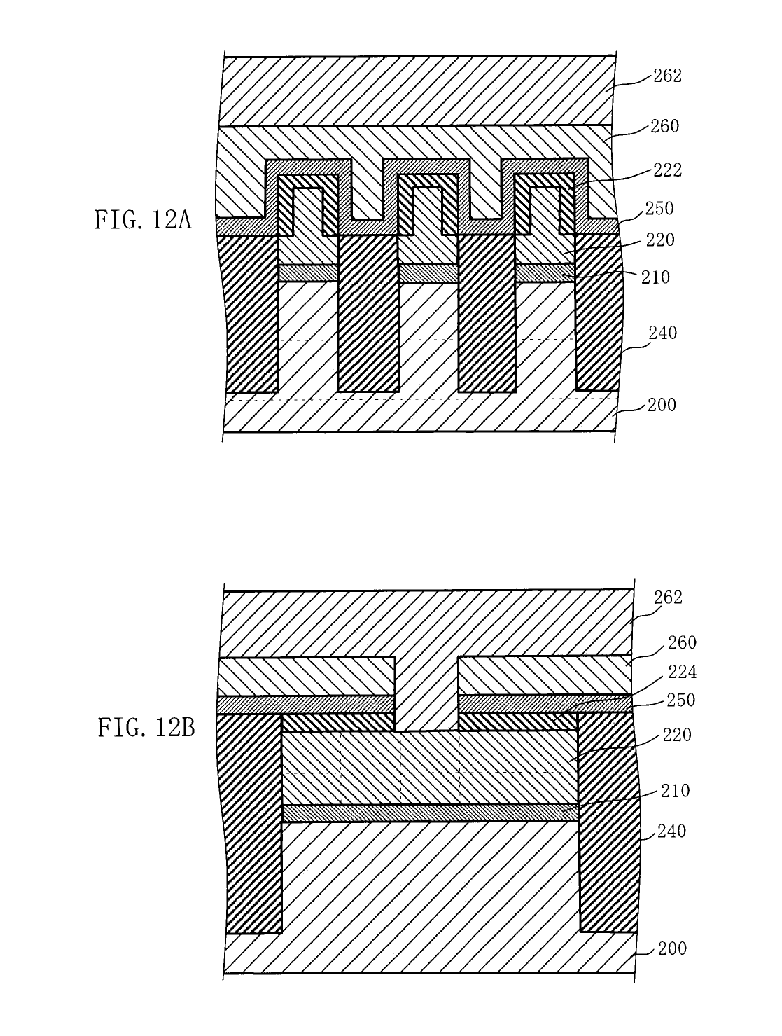

FIGS. 12A and 12B show process sectional views of the method for fabricating a semiconductor device according to the first embodiment. FIGS. 12A and 12B show the metallic film formation process (S124) in FIG. 1. Subsequent processes will be described later.

In FIG. 12A, as the metallic film formation process (S124), a metallic film 262 is formed on the Si film 260 by using, for example, the CVD method to a thickness of, for example, 30 nm or less. The metallic film 262 functions as a portion of the control gate (CG). That is, the control gate has a laminated structure (control gate portion) formed by the Si film 260 to be a polysilicon film and the metallic film 262 being stacked. The laminated film of the Si film 260 and the metallic film 262 functions as a word line in a memory device. For example, a tungsten (W) film is suitably used as the metallic film 262. In place of the W film, a laminated film of a W film and a tungsten nitride (WN) may be used. Alternatively, a W film alone or a laminated film of a W film and tungsten nitride (WN) maybe used as a control gate without using the Si film 260. Alternatively, a laminated film of a W film and another conductive film may be adopted as the control gate. It is still better to form a silicide film by silicifying the interface between the Si film 260 and the metallic film 262.

After the metallic film formation process (S124) described above being performed, an opening to be a gate pattern groove maybe formed on both sides of a gate structure portion along the longitudinal direction of the CG (word line). Such an opening is suitably formed, for example, in the width of 20 nm or less at intervals of 40 nm or less. Accordingly, the Si film 220 is separated for each memory cell along a direction perpendicular to the longitudinal direction of the CG (word line) to form a floating gate (also called a floating gate or a charge storage layer) and also the control gate (CG) is processed into a word line form. Such an opening is caused to pass through the metallic film 262 to the Si film 220 by the lithography process and the dry etching process (both are not shown). Then, an n-type semiconductor region is formed in a region between gate structures on the surface of the p-type semiconductor substrate 200 by ion implantation of an n-type impurity into the semiconductor substrate 200 via the gate dielectric film 210 at the bottom of the opening. Such an n-type semiconductor region functions as a source/drain region (S.D). A p-type semiconductor region sandwiched between n-type semiconductor regions functions as a channel region in which a gate region (G) is formed in an upper portion thereof. With the above configuration, a NAND string structure in which a plurality of cell (gate structure) sharing a source portion of one of adjacent cells and a drain portion of the other cell (not shown) is aligned is formed.

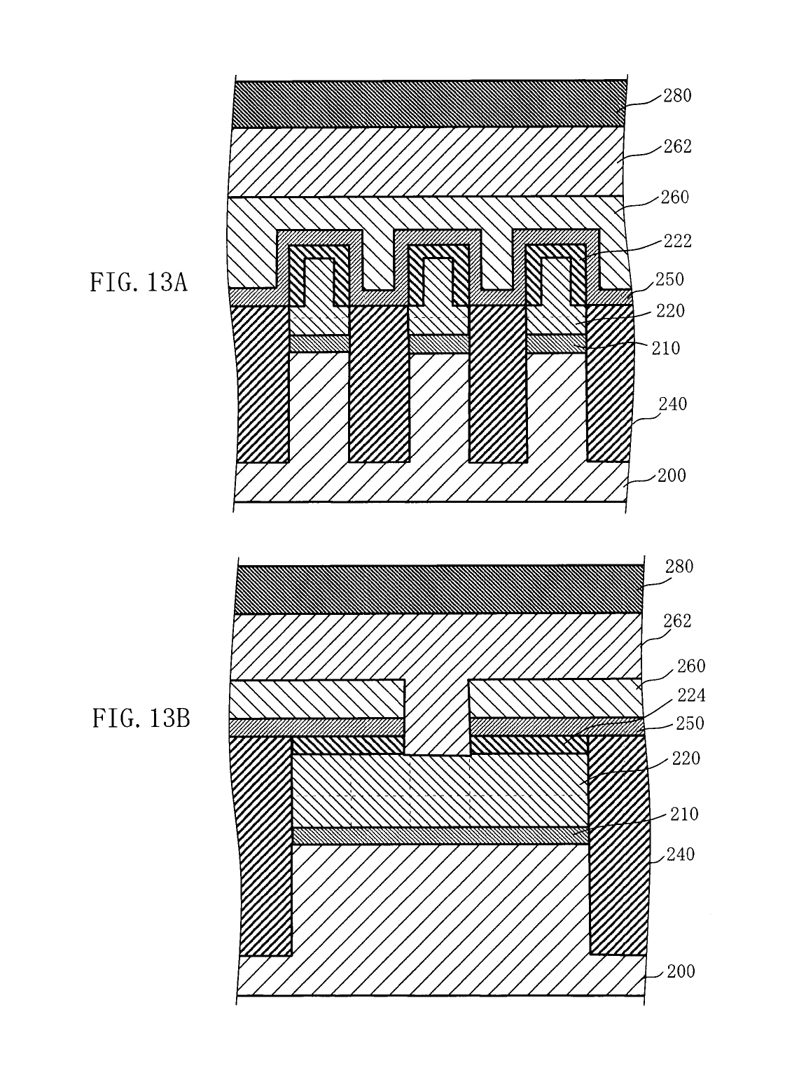

FIGS. 13A and 13B are sectional views showing a state in which an inter-level dielectric is formed after a gate structure is formed by the method for fabricating a semiconductor device according to the first embodiment. A dielectric film 280 is formed on gate structures and between gate structures formed as described above. FIGS. 13A and 13B show sections in a direction along the longitudinal direction of the control gate (CG) (word line) and thus, the dielectric film 280 is formed on the metallic film 262.

In the foregoing, an embodiment has been described with reference to concrete examples. However, the present disclosure is not limited to the concrete examples.

In addition, all semiconductor devices and all methods for fabricating a semiconductor device that include elements of the present disclosure and whose design can be changed as appropriate by persons skilled in the art are included in the scope of the present disclosure.

While techniques normally used in the semiconductor industry such as cleaning before and after treatment are not described for convenience of description, it is needless to say that such techniques are included in the scope of the present disclosure.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first dielectric film formed above a semiconductor substrate;
a floating gate formed above the first dielectric film by using a silicon film;
a second dielectric film for element isolation of semiconductor elements arranged on a side of a side face of the floating gate and embedded between a height position of a lower portion of the side face of the floating gate and a height position inside the semiconductor substrate; and
a third dielectric film formed to cover an upper surface of the floating gate and a side face portion of the floating gate up to a height position of an upper surface of the second dielectric film, of the side face of the floating gate continuing from the upper surface of the floating gate,
wherein the floating gate includes an impurity layer formed on the upper surface of the floating gate and the side face of the floating gate along an interface between the floating gate and the third dielectric film and containing at least one of carbon (C), nitrogen (N), and fluorine (F) as an impurity.

2. The device according to claim 1, wherein the impurity layer is formed in an entire interface between the floating gate and the third dielectric film.

3. The device according to claim 1, wherein the impurity in an upper portion of the floating gate upper than the height position of the upper surface of the second dielectric film has a higher concentration than that inua lower portion of the floating gate lower than the height position of the upper surface of the second dielectric film.

4. The device according to claim 1, wherein the floating gate is formed by using a p-type silicon film.

5. The device according to claim 4, wherein the floating gate contains boron (B) as a p-type dopant.

6. The device according to claim 1, wherein the impurity in the impurity layer has a concentration of 1×10¹⁸ to 1×10²²/cm³.

7. The device according to claim 1, further comprising:
a peripheral circuit arranged in a periphery of the floating gate and formed by using a silicon film,
wherein the silicon film in the floating gate has a higher concentration of the impurity per volume than the silicon film in the peripheral circuit.

8. The device according to claim 7, wherein the second dielectric film is arranged also on a side of a side face of the peripheral circuit and embedded between a height position higher than the lower portion of the side face of the floating gate and the height position inside the semiconductor substrate.

9. A semiconductor device, comprising:
a floating gate formed in a first region above a semiconductor substrate by using a silicon film containing at least one of carbon (C), nitrogen (N), and fluorine (F) as an impurity via a first dielectric film; and
a peripheral circuit formed in a second region above the semiconductor substrate by using the silicon film in a same layer as the floating gate,
wherein the silicon film in the floating gate has a higher concentration of the impurity of at least one of the carbon (C), the nitrogen (N), and the fluorine (F) per volume than the silicon film in the peripheral circuit.

10. The device according to claim 9, wherein the silicon film in the peripheral circuit is used as a resistance element.

11. A method for fabricating a semiconductor device, comprising:
forming a first dielectric film above a semiconductor substrate;
forming a floating gate material film above the first dielectric film by using silicon;
forming openings for element isolation passing through the floating gate material film and the first dielectric film and halfway through the semiconductor substrate;
filling the openings with a second dielectric film;
etching the second dielectric film up to a height position halfway through the floating gate material film;
doping at least one of carbon (C), nitrogen (N), and fluorine (F) into an upper surface and a side face of the floating gate material film as an impurity after the etching; and
forming a third dielectric film along an impurity layer formed on the upper surface of the floating gate material film and a side face portion of the floating gate material film up to a height position of an upper surface of the second dielectric film, of the side face of the floating gate material film by the impurity being doped.

12. The method according to claim 11,
wherein the openings are formed in a first region where a floating gate is formed and a second region where a peripheral circuit of the floating gate is formed,
both of the openings in the first region and the second region are filled with the second dielectric film, and
when the second dielectric film is etched, the second dielectric film is etched in the first region and the second dielectric film is left without being etched in the second region.

13. The method according to claim 11, wherein the floating gate material film is formed by using silicon containing boron (B) as a p-type dopant.

14. The method according to claim 13, further comprising: doping boron (B) further into the floating gate material film during doping the impurity or before or after doping the impurity.

15. The method according to claim 11, wherein the impurity is doped by using a plasma doping method.

16. The method according to claim 11, wherein the impurity is doped by using a gas phase doping method.

17. The method according to claim 11, wherein the impurity in the impurity layer has a concentration of 1×10¹⁸ to 1×10²²/cm³.

18. The method according to claim 12, wherein the impurity layer is formed on the upper surface of the floating gate material film in the second region by the impurity being doped.

19. The method according to claim 18, wherein the floating gate material film in the first region has a higher concentration of the impurity per volume than the floating gate material film in the second region.

20. The method according to claim 11, further comprising: forming a control gate above the third dielectric film.
